(19) United States
(12) Patent Application Publication
(10) Pub. No.: US 2018/0258550 A1
(43) Pub. Date: Sep. 13, 2018

(54) Growth Method of Aluminum Nitride

(71) Applicant: Epileds Technologies, Inc., Tainan City (TW)

(72) Inventors: Kung-Hsieh Hsu, Tainan City (TW); Ming-Sen Hsu, Tainan City (TW)

(21) Appl. No.: 15/635,796

(22) Filed: Jun. 28, 2017

(30) Foreign Application Priority Data
Mar. 13, 2017 (TW) 106108215

(51) Int. Cl. C30B 25/18; H01L 21/02; C30B 29/40; C23C 16/34

(52) U.S. Cl. CPC C30B 25/18; H01L 21/0242; H01L 21/02458; H01L 21/0254; H01L 21/02378; C30B 29/403; C23C 16/34; H01L 21/02381; H01L 21/0262

(57) ABSTRACT

The present application provides a growth method of aluminum nitride (AlN), including the following steps: providing a substrate; using a metal organic chemical vapor deposition (MOCVD) device to simultaneously supply metal source gas, nitrogen source gas and group VI element source gas to the substrate to form an AlN nucleation layer on the substrate; and using the MOCVD device to simultaneously supply the nitrogen source gas and the metal source gas to the AlN nucleation layer to form an AlN crystalline layer on the AlN nucleation layer.

### CROSS-REFERENCE TO RELATED APPLICATION

This application claims priority from the Taiwan Patent Application No. 106108215 filed on Mar. 13, 2017 at the Taiwan Intellectual Property Office, the content of which is hereby incorporated by reference in its entirety for all purposes.

### BACKGROUND OF THE INVENTION

### 1. Field of the Invention

The present disclosure relates to a growth method of aluminum nitride (AlN), and in particular, to a growth method of AlN monocrystalline on the substrate.

### 2. Description of the Related Art

AlN is semiconductor material of group III/V element, and also is artificial ceramics material. AlN has hexagonal wurtzite structure, and the nitrogen atom and the aluminum are combined to form the tetrahedral structure through the covalent bond. In addition, an energy gap of the AlN is about 6.2 ev, and AlN has the highest energy gap among the semiconductor material of the group III/V elements. AlN is the colorless and transparent material having properties of high thermal conductivity, high hardness, high temperature resistance, chemical resistance, piezoelectric, and biological affinity, and thus is suitable to be applied in the semiconductor field.

Currently, one of the chemical vapor deposition (CVD) and the physical vapor deposition (PVD) is used to perform the deposition of the AlN thin film, wherein the PVD can be categorized to the molecular beam epitoxy (MBE), the medium frequency magnetron sputtering and the direct current/radio frequency magnetron sputtering.

To perform the polarity growth method of group III element, a process of merely providing group III element material (such as Al material) is configured to make the group III element atoms formed with the supersaturated state. However, in such situation, in the initial stage of the monocrystalline growth of the nitride group III element, the supply quantity and supply method of the group III element material should be controlled precisely. To perform the stable polarity growth of the group III element, the supply quantity of the group III element material should be increased, and in other hand, it shows the decreasing trend of the crystalline quality.

Accordingly, there is an urgent need to provide a growth method of AlN to enhance the AlN crystalline quality.

### SUMMARY OF THE INVENTION

In view of the above-mentioned problems, it is an object of the present disclosure to provide a growth method of AlN, including the following steps: providing a substrate; using a metal organic chemical vapor deposition (MOCVD) device to simultaneously supply metal source gas, nitrogen source gas and group VI element source gas to the substrate to form an AlN nucleation layer on the substrate; and using the MOCVD device to simultaneously supply the nitrogen source gas and the metal source gas to the AlN nucleation layer to form an AlN crystalline layer on the AlN nucleation layer.

Preferably, the step for using the MOCVD device to supply the group VI element source gas comprises disposing the substrate in interior of a chamber and using a heating source to heat a top cover and a wafer supporting plate of the chamber, so as to supply the group VI element source gas.

Preferably, the top cover is a quartz top cover.

Preferably, the wafer supporting plate is a quartz supporting plate.

Preferably, a thickness of the quartz top cover is 3.0 mm.

Preferably, a distance from the top cover to the wafer supporting plate is about 7.0 mm through 10.0 mm.

Preferably, the distance from the top cover to the wafer supporting plate is 9.5 mm.

Preferably, the growth method of AlN further comprises steps as follows: configuring the top cover, the wafer supporting plate and the heating source to connect a distance regulating device, so as to control positions of the top cover, the wafer supporting plate and the heating source.

Preferably, the chamber comprises a quartz inner wall therein.

Preferably, the step for using the MOCVD device to supply the group VI element source gas comprises using tellurium dithyl (DETe) as a metal organic (MO) source.

Accordingly, by using the growth method of AlN in the present disclosure, the concentration layer of the group VI element source gas in the AlN nucleation layer and the thickness of AlN nucleation layer can be controlled within specific ranges. When the AlN monocrystalline layer is formed on the AlN nucleation layer, by the help of the stable polarity growth of AlN, AlN monocrystalline layer has the monocrystalline layer with the better monocrystalline quality.

Furthermore, at the step of nucleation, by using the property of the quartz which the quartz is decomposed into aluminum and oxygen, an oxygen doping objective is achieved, and by using the surface shape of the quartz, the net crack due the nucleation of using oxygen can be improved. Moreover, during the AlN nucleation, the DETe can be used as the MO source, and thus has the effect of improving the growth quality of the subsequent grown AlN monocrystalline thin film.

### BRIEF DESCRIPTION OF THE DRAWINGS

The foregoing and other features and advantages of the present invention will become more apparent from the following detailed description of exemplary embodiments thereof with reference to the accompanying drawings in which:

FIG. 1 is a flow chart of a growth method of AlN according to a first embodiment of the present disclosure.

FIG. 2 is a schematic diagram showing a stack structure formed by using the growth method of AlN of the present disclosure.

FIG. 3 is a flow chart of a growth method of AlN according to a second embodiment of the present disclosure.

FIG. 4 is a schematic diagram showing a MOCVD device is used in the growth method of AlN of the present disclosure.

FIG. 5 is an X-ray rocking curve (XRC) diagram of comparison examples of the growth methods of AlN of the present disclosure.

FIG. 6(a) through FIG. 6(d) are photograph diagrams of surface shapes of comparison examples of the growth methods of AlN of the present disclosure.

FIG. 7 is a photograph diagram of a surface shape while the oxygen source is provided as the group VI element source gas.

FIG. 8 is a flow chart of a growth method of AlN according to a third embodiment of the present disclosure.

FIG. 9(a) and FIG. 9(b) are photograph diagrams of surface shapes of comparison examples of the growth methods of AlN of the present disclosure while the DETe is used.

### DESCRIPTION OF THE EXEMPLARY EMBODIMENTS

While embodiments are described with reference to the accompanying drawings, it is to be understood that various changes and modifications can be made in the described technology without departing from the spirit and scope thereof. Further, it should be understood that the described technology is not limited to the specific embodiments thereof, and various changes, equivalences and substitutions can be made without departing from the scope and spirit of the described technology.

As used herein, the term “and/or” includes any or all combinations of one or more related item items. When the term “at least one of” is used to prefix an element list, the entire inventory element is associated rather than the individual elements in the list.

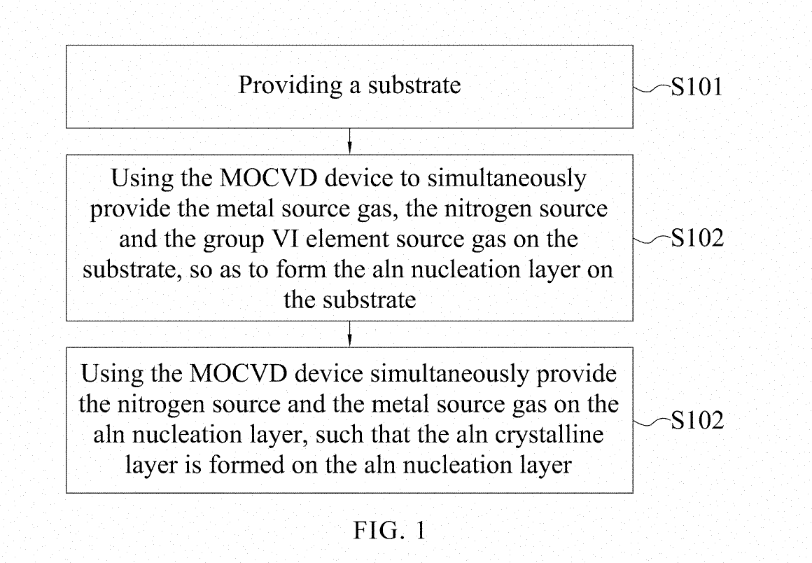

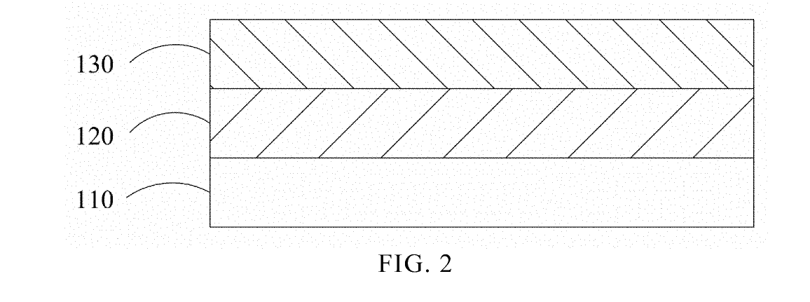

Refer to FIG. 1 and FIG. 2. FIG. 1 is a flow chart of a growth method of AlN according to a first embodiment of the present disclosure, and FIG. 2 is a schematic diagram showing a stack structure formed by using the growth method of AlN of the present disclosure.

The followings are described in order to illustrate the present disclosure. According to the embodiment of the present disclosure, a growth method of AlN is provided, wherein the MOCVD is used to grow the AlN monocrystalline layer. The MOCVD process mainly provides the group III element material gas, such as the organic metal gas of triethylaluminum, nitrogen source, and material gas of ammonia gas on the substrate, such that the AlN monocrystalline layer is formed on the substrate. The method of the present disclosure can be used in the device which is able to perform the MOCVD process, the present disclosure does not limit the types of the MOCVD device, and the MOCVD device of the prior art or the MOCVD device sold in the market can be used. The method of the present disclosure comprises steps as follows.

Step S101: providing a substrate 110. The substrate 110 used by the method of the present disclosure is a substrate on which the AlN monocrystalline layer is grown, and the type of the substrate is not limited in the present disclosure. For example, the sapphire substrate can be used, or alternatively, the silicon substrate or silicon carbide substrate can be used. In addition, the thickness of the substrate 110 is also not limited, and for the person with the ordinary skill in the art, the thickness is considered and determined according to the manufacturing cost and convenience for performing processes. Preferably, the substrate 110 is a pattern sapphire substrate (PSS) which has a thickness not less than 0.1 mm and not larger than 1.0 mm, and more preferably, cannot be less than 0.2 mm and larger than 0.5 mm.

Step S102: using the MOCVD device to simultaneously provide the metal source gas, the nitrogen source and the group VI element source gas on the substrate 110, so as to form the AlN nucleation layer 120 on the sapphire substrate, for example. The AlN nucleation layer 120 can be used to decrease the dislocation due to the lattice mismatch between the sapphire substrate and the nitride monocrystalline formed during subsequent processing step, further to decrease the deformation due to the difference between thermal expansion coefficients, and to suppress crack generation. The AlN nucleation layer 120 can be single one layer or a stack structure having a plurality of layers. For example, the AlN nucleation layer 120 can further comprise the lattice buffer layer formed by the crystalline comprising AlN.

In addition, while the group VI element source gas and the metal source gas are simultaneously provided on the substrate 110, it can ensure that the polarity growth of AlN is stably proceeding. Furthermore, the concentration of the group VI element source gas within the AlN nucleation layer 120 and the thickness of the AlN nucleation layer 120 can be controlled within specific ranges, and by the help of the stably polarity growth of AlN, the AlN monocrystalline layer 130 can have a monocrystalline layer with better crystalline quality while the AlN monocrystalline layer 130 is formed on the AlN nucleation layer 120.

Preferably, the substrate 110 can be preprocessed in the oxygen environment before the AlN nucleation layer 120 is formed, such that the thinner AlN nucleation layer 120 is obtained, and the AlN monocrystalline layer 130 has the better crystalline quality.

Next, step S103 is executed, the MOCVD device is used to simultaneously provide the nitrogen source and the metal source gas on the AlN nucleation layer 120, such that the AlN crystalline layer 130 is formed on the AlN nucleation layer 120.

Specifically, while the AlN monocrystalline layer 130 is formed, in order to decrease the accidentally mixed impurities, the group VI element source gas in the present embodiment can be oxygen gas. Though the method can control the concentration of the oxygen gas more precisely while forming the AlN nucleation layer 120, the high oxygen concentration affects the lateral grow of AlN, thus decreasing the quality of the subsequent formed AlN monocrystalline layer 130. In other words, the situation can be presented by the XRC diagram which the ω scan of X-ray diffraction (i.e. showing the wave indicator of c axis of the lattice) is performed on the (10-12) surface of AlN with the density of the mixed dislocation and blade dislocation, wherein the defect density can be estimated according to the FWHM of (002) or (102) surface. The smaller the FWHM of (002) or (102) surface is, the smaller the defect density is.

Thus, for the above problems, preferably, the mounts of the group VI element gas and impurities should be decreased as much as possible and when heating the substrate 110, wherein the group VI element gas is able to suppress the generation of material of peripheral components of the substrate 110. Specifically, the peripheral device which is heated up to more than 1000° C. by the thermal radiation from the substrate can be used, and the device which at least partial surface exposing the material gas is formed by quartz can be used.

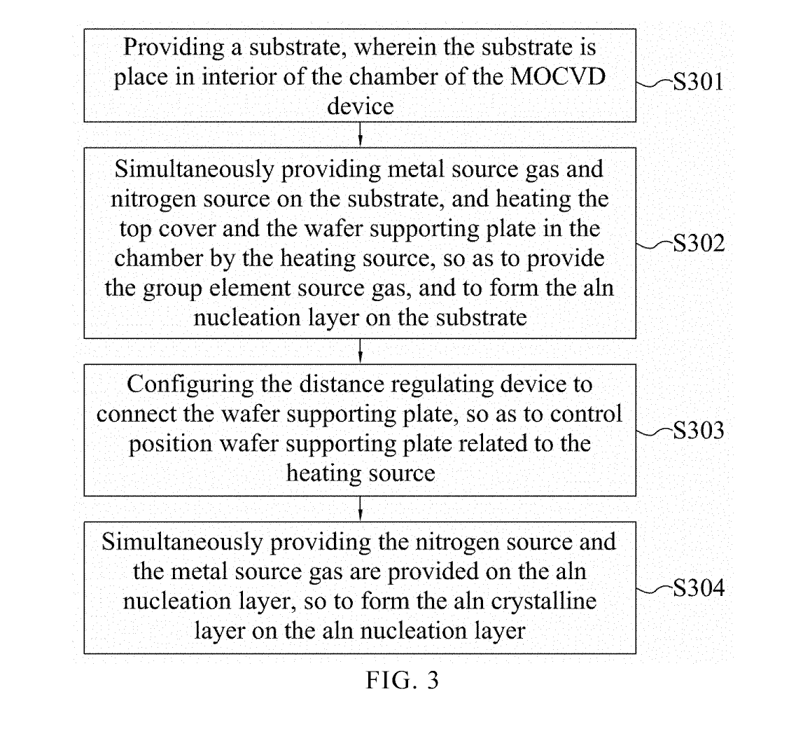

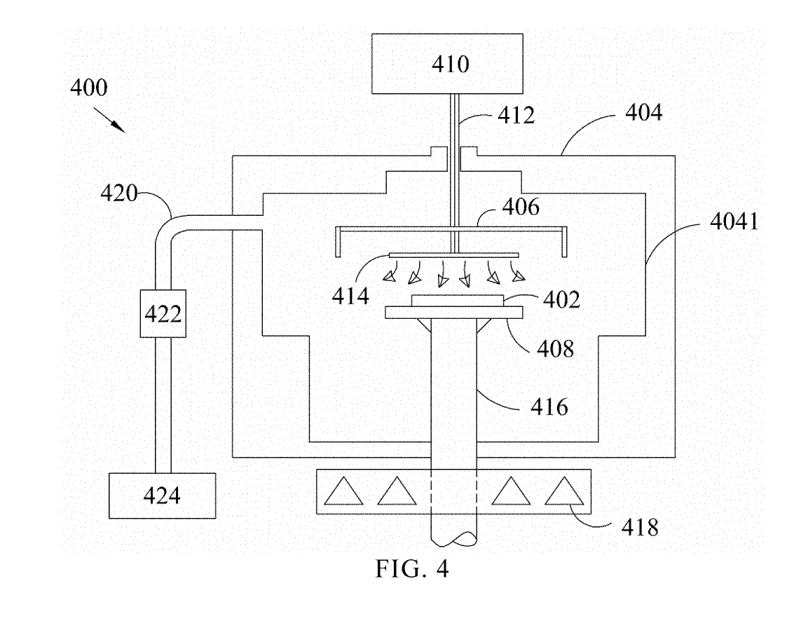

Therefore, refer to FIG. 3 and FIG. 4, FIG. 3 is a flow chart of a growth method of AlN according to a second embodiment of the present disclosure, and FIG. 4 is a schematic diagram showing a MOCVD device is used in the growth method of AlN of the present disclosure.

Step S301: providing a substrate 402, wherein the substrate 402 is placed in interior of the chamber 404 of the MOCVD device 400. The MOCVD device 400 comprises a chamber 404, a top cover 406, a wafer supporting plate 408, a gas transferring system 410, a gas transferring tube 412, a gas distributing nozzle 414, a distance regulating device 416, a heating source 418, and exhaust tube 420, a valve system 422 and a vacuum system 424. The substrate 402 can be the sapphire substrate, silicon substrate and silicon carbide substrate.

Step S302: simultaneously providing metal source gas and nitrogen source on the substrate 402, and heating the top cover 406 and the wafer supporting plate 408 in the chamber by the heating source 418, so as to provide the group element source gas, and to form the AlN nucleation layer on the substrate 402. The metal source gas and the nitrogen source is transferred into the chamber 414 by using the gas transferring system 410, the gas transferring tube 412 and the gas distributing nozzle 414, and the exhaust tube 420, the valve system 422 and the vacuum system 424 are used to maintain the vacuum degree of the chamber 404.

Specifically, in the embodiment, structures of the wafer supporting plate 408, the top cover 406 and the inner wall of chamber 404 of the MOCVD device 400 are selectively made of quartz. In other words, the top cover 414 can the quartz top cover, the wafer supporting plate 408 can be the quartz supporting plate, and the chamber 404 can have the quartz inner wall. By the above configuration, at the nucleation step, the quartz is decomposed into aluminum and oxygen at the high temperature so as to achieve an oxygen doping objective. Thus, the group VI element source gas in the previous embodiment can be replaced, i.e. the oxygen gas source can be replaced.

Optionally, step S303 can be executed. Step S303: configuring the distance regulating device 416 to connect the wafer supporting plate 408, so as to control position wafer supporting plate 408 related to the heating source 418. Though FIG. 3 merely depicts the distance regulating device 416 connects the wafer supporting plate 408, it can be known that the distance regulating device 416 can connect the top cover 406, the wafer supporting plate 408 and the heating source 418, such that the position of the quartz structure related to the heating source 418 can be controlled, and the mount of the oxygen decomposition can be further controlled. Furthermore, the wafer supporting plate 408 in the embodiment is configured to support one or more substrate 402, and the distance regulating device 416 can be further configured to rotate the wafer supporting plate 408 to achieve uniform growth of AlN.

At step S304, the nitrogen source and the metal source gas are simultaneously provided on the AlN nucleation layer formed in step S302 (or alternatively, simultaneously formed in step S303), so to form the AlN crystalline layer on the AlN nucleation layer. In the similar manner, the nitrogen source and the metal source gas can be continuously transferred into the chamber 404 by using the gas transferring system 410, the gas transferring tube 412 and the gas distributing nozzle 414.

However, in the above embodiments, a plurality of variable factors should be controlled. For example, whether the quartz top cover is used, whether the quartz supporting plate is used, whether both of the quartz top cover and the quartz supporting plate are used, and distance between the wafer supporting plate 408 and the op cover 406. Thus, the following comparison examples with different variable factors are given, and XRC diagram of the comparison examples are rendered, so as to estimate the defect density according to the (102) surface of FWHM. The photograph diagrams of surface shapes of the grown AlN monocrystalline layer of different comparison examples are provided.

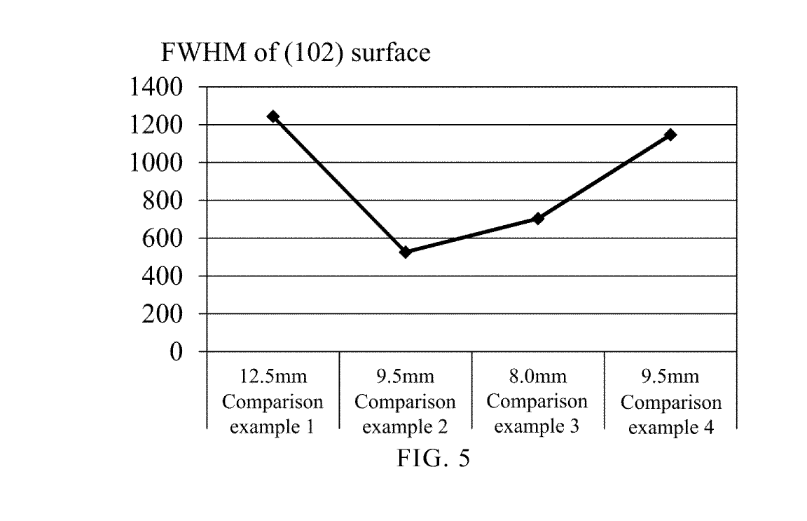

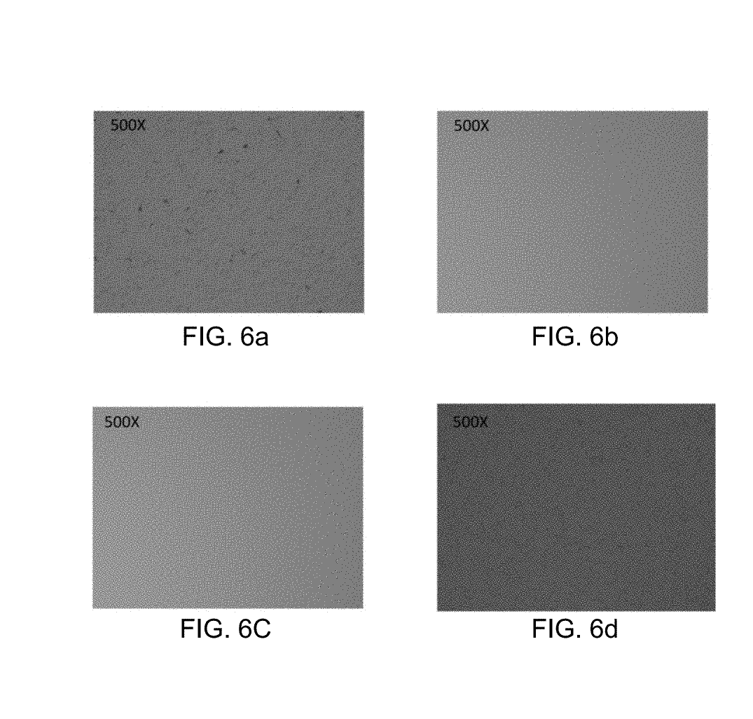

Refer to FIG. 5 and FIG. 6(a) through FIG. 6(d). FIG. 5 is an X-ray rocking curve (XRC) diagram of comparison examples of the growth methods of AlN of the present disclosure, and FIG. 6(a) through FIG. 6(d) are photograph diagrams of surface shapes of comparison examples of the growth methods of AlN of the present disclosure.

Refer to Table 1, Table 1 shows the results of FWHM of the measured (102) surface and conditions of each comparison examples:

TABLE 1

| | | | | comparison |
|---|---|---|---|---|
| | comparison | | | example 4 |
| | example 1 | | | quartz top |
| | without | comparison | comparison | cover and |
| | quartz | example 2 | example 3 | quartz |
| | elements | quartz top | quartz top | supporting |
| | installed | cover | cover | plate |
| thickness of | | 3.0 mm | 3.0 mm | 3.0 mm |
| the quartz | | | | |
| distance from | 12.5 mm | 9.5 mm | 8.0 mm | 9.5 mm |
| the wafer | | | | |
| supporting | | | | |
| plate to the | | | | |
| top cover | | | | |
| XRD FWHM | 1243 | 526 | 703 | 1146 |
| 102 (arcsec) | | | | |

In the above comparison examples 1-4, the PSS is used in the MOCVD device to form the AlN epitaxy thin film, the surface is poorest and the FWHM of the (102) surface of XRD is highest (i.e. the defect density is highest and the growth quality is poorest) while no quartz components are used. While the quartz top cover is used in the comparison example, the FWHM of the (102) surface of XRD is lowest (i.e. the defect density is lowest and the growth quality is best). In addition, when the quartz top cover approaches the heating source closer, the high temperature results that more decomposed oxygen atoms, and though the surface shape is best, the FWHM of the (102) surface of XRD is slightly higher (i.e. the growth quality is slightly poorer). However, the comparison example 4 shows that if the quartz top cover and the quartz wafer supporting plate are used, the surface shape will have a plurality of holes. These holes are caused since the patterns of the PSS are not covered by the AlN monocrystalline layer. The results show excessive quartz components will cause excessive released oxygen, thus affecting the lateral growth of AlN and increasing FWHM of the (102) surface of XRD (i.e. the growth quality is decreased).

From the above results, it can be known that the growth quality of the usage of the top cover and the quartz supporting plate is better than that without using the quartz components. When the thickness of the quartz top cover is 3.0 mm and the distance between top cover and the wafer supporting plate is about 7.0 mm through 10.0 mm, the growth quality is better. The best case is to merely use the quartz top cover, and distance between the top cover and the wafer supporting plate is 9.5 mm, and under such case, the growth quality is best.

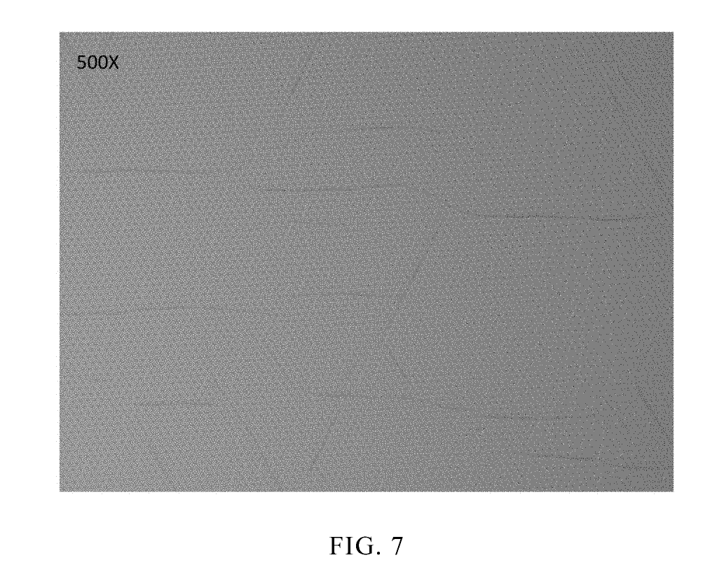

In addition, refer to FIG. 7, and FIG. 7 is a photograph diagram of a surface shape while the oxygen source is provided as the group VI element source gas. As mentioned above, though the oxygen concentration can be controlled precisely while forming the AlN nucleation layer, the high oxygen concentration still affects the lateral growth of AlN, thus causing the quality of the subsequent grown AlN monocrystalline layer decreased. As show in the drawings, when forming the AlN nucleation layer, the usage of the oxygen gas causes the net cracks as shown in the drawings, and that is, the growth quality is poor. Thus, the surface shape of the usage of quartz component(s) is still better than that of the usage of oxygen gas during the nucleation step.

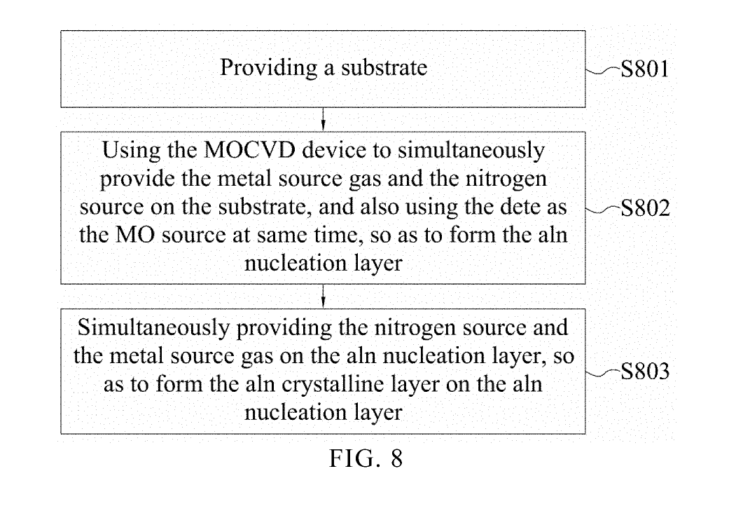

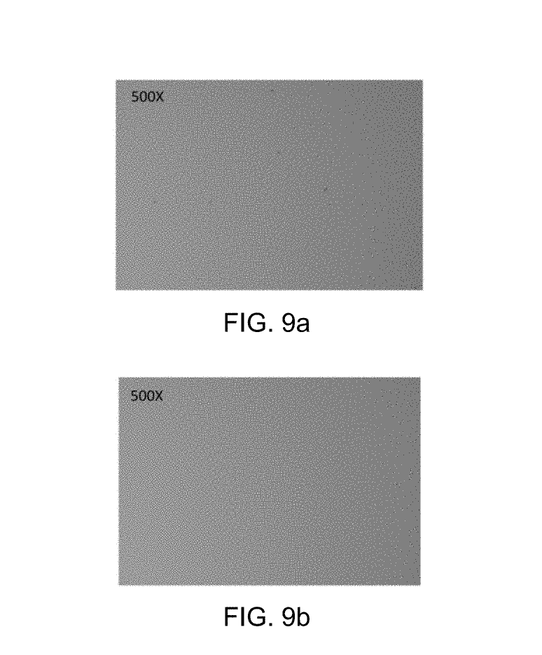

Accordingly, to solve the above problems, the present disclosure provides another one growth method of AlN. Refer to FIG. FIG. 8, FIG. 9(a) and FIG. 9(b), FIG. 8 is a flow chart of a growth method of AlN according to a third embodiment of the present disclosure, and FIG. 9(a) and FIG. 9(b) are photograph diagrams of surface shapes of comparison examples of the growth methods of AlN of the present disclosure while the DETe is used.

The growth method of AlN of the third embodiment comprises the following steps.

Step S801: providing a substrate. The substrate is preferably the sapphire substrate, the silicon substrate or silicon carbide substrate.

Step S802: using the MOCVD device to simultaneously provide the metal source gas and the nitrogen source on the substrate, and also using the DETe as the MO source at same time, so as to form the AlN nucleation layer.

At step S803, simultaneously providing the nitrogen source and the metal source gas on the AlN nucleation layer formed in step S702, so as to form the AlN crystalline layer on the AlN nucleation layer.

As shown in FIG. 9(a) and FIG. 9(b), the DETe of the flow rates of 100 sccm and 300 sccm are used. From the results, it can be known that the doping of Te in the step of AlN nucleation also can improve quality of the subsequent grown AlN thin film. In addition, from the example of oxygen doping in FIG. 7, merely the epitaxy thin film having about half area without cracks is obtained, and the usage of Te makes the AlN monocrystalline thin film have no net cracks. In the similar manner, other group VI element (such as S, Se, Po) can be doped in the step of AlN nucleation to form the AlN monocrystalline layer, such that the quality of the thin film is improved, and the crack generation is suppressed.

Accordingly, by using the growth method of AlN in the present disclosure, the concentration layer of the group VI element source gas in the AlN nucleation layer and the thickness of AlN nucleation layer can be controlled within specific ranges. When the AlN monocrystalline layer is formed on the AlN nucleation layer, by the help of the stable polarity growth of AlN, AlN monocrystalline layer has the monocrystalline layer with the better monocrystalline quality.

Furthermore, at the step of nucleation, by using the property of the quartz which the quartz is decomposed into aluminum and oxygen, an oxygen doping objective is achieved, and by using the surface shape of the quartz, the net crack due the nucleation of using oxygen can be improved. Moreover, during the AlN nucleation, the DETe can be used as the MO source, and thus has the effect of improving the growth quality of the subsequent grown AlN monocrystalline thin film.

The above-mentioned descriptions represent merely the exemplary embodiment of the present disclosure, without any intention to limit the scope of the present disclosure thereto. Various equivalent changes, alternations or modifications based on the claims of present disclosure are all consequently viewed as being embraced by the scope of the present disclosure.

1. A growth method of aluminum nitride (AlN), comprising:
providing a substrate;
forming a group VI element doped AlN nucleation layer on the substrate by simultaneously supplying metal source gas and nitrogen source gas and heating a top cover and a wafer supporting plate in a metal organic chemical vapor deposition (MOCVD) device without supplying group VI element source gas;
using the MOCVD device to simultaneously supply the nitrogen source gas and the metal source gas to the AlN nucleation layer to form an AlN crystalline layer on the AlN nucleation layer.

2. (canceled)

3. The growth method of AlN according to claim 1, wherein the top cover is a quartz top cover.

4. The growth method of AlN according to claim 1, wherein the wafer supporting plate is a quartz supporting plate.

5. The growth method of AlN according to claim 3, wherein a thickness of the quartz top cover is 3.0 mm.

6. The growth method of AlN according to claim 1, wherein a distance from the top cover to the wafer supporting plate is about 7.0 mm through 10.0 mm.

7. The growth method of AlN according to claim 1, wherein the distance from the top cover to the wafer supporting plate is 9.5 mm.

8. The growth method of AlN according to claim 1, further comprising:
configuring the top cover, the wafer supporting plate and the heating source to connect a distance regulating device, so as to control positions of the top cover, the wafer supporting plate and the heating source.

9. The growth method of AlN according to claim 1, wherein the chamber comprises a quartz inner wall therein.

10. (canceled)
